(19) United States
(12) Patent Application Publication
(10) Pub. No.: US 2026/0231671 A1
(43) Pub. Date: Aug. 6, 2026

(54) APPARATUS AND METHOD FOR FORMATION OF METAL-HALIDE PEROVSKITE FILMS

(71) Applicant: Arizona Board of Regents for and on behalf of Arizona State University, Scottsdale, AZ (US)

(72) Inventors: Abdulwahab Alasfour, Tempe, AZ (US); Zachary Holman, Phoenix, AZ (US)

(21) Appl. No.: 19/146,372

(22) PCT Filed: Jan. 9, 2024
(86) PCT No.: PCT/US2024/010861

§ 371 Date: Jul. 8, 2025

Related U.S. Application Data
(60) Provisional application No. 63/479,025, filed on Jan. 9, 2023.

(51) Int. Cl. H10K 85/50; H10K 30/50; H10K 71/12; H10K 71/40

(52) U.S. Cl. CPC H10K 85/50; H10K 30/50; H10K 71/12; H10K 71/441

(57) ABSTRACT

Forming a perovskite film on a substrate includes atomizing a perovskite precursor composition to yield perovskite precursor droplets. accelerating the perovskite precursor droplets under sub-atmospheric pressure toward the substrate, collecting the perovskite precursor droplets on the substrate to yield a perovskite precursor layer on the substrate, and forming a perovskite film on the substrate. The perovskite precursor composition includes one or more perovskite precursors. The perovskite film has the crystal structure ABX₃, where A represents one or more organic cations, one or more inorganic cations, or both, B represents one or more metal cations, and X represents one or more halide anions. A coated substrate includes a substrate and a perovskite precursor composition on the substrate. The perovskite precursor composition comprises a solvent and one or more perovskite precursors, and removing the solvent from the perovskite precursor composition yields a perovskite film on the substrate.

### CROSS-REFERENCE TO RELATED APPLICATION

This application claims the benefit of U.S. Patent Application No. 63/479,025 filed on Jan. 9, 2023, which is incorporated by reference herein in its entirety.

### TECHNICAL FIELD

This invention relates to methods and systems for the deposition of perovskite thin films.

### BACKGROUND

Perovskite photovoltaic cells have been used separately and in conjunction with bottom cells to form tandem photovoltaic cells.

### SUMMARY

This disclosure describes methods and systems for the deposition of metal-halide perovskite thin films. The films may be deposited on any substrate translated in a linear fashion, including webs, wafers, and glass sheets. The resulting films are uniform and dense, with few defects and high external radiative efficiency, suitable for use in photovoltaic and other optoelectronic devices, and they may be made conformal to textured surfaces. The methods and systems are scalable to coatings meters wide with line throughputs of several meters per minute.

Although the disclosed inventive concepts include those defined in the attached claims, it should be understood that the inventive concepts can also be defined in accordance with the following embodiments.

Embodiment 1 is a method of forming a perovskite film on a substrate, the method comprising:
atomizing a perovskite precursor composition to yield perovskite precursor droplets, wherein the perovskite precursor composition comprises one or more perovskite precursors;
accelerating the perovskite precursor droplets under sub-atmospheric pressure toward the substrate;
collecting the perovskite precursor droplets on the substrate to yield a perovskite precursor layer on the substrate; and
forming, from the perovskite precursor layer on the substrate, a perovskite film on the substrate, wherein the perovskite film has the crystal structure ABX₃, where:
   A represents one or more organic cations, one or more inorganic cations, or one or more of both,
   B represents one or more metal cations, and
   X represents one or more halide anions.

Embodiment 2 is the method of embodiment 1, wherein the perovskite precursor composition further comprises a solvent.

Embodiment 3 is the method of embodiment 2, further comprising removing the solvent from the perovskite precursor droplets before or after collecting the perovskite precursor droplets on the substrate.

Embodiment 4 is the method of embodiment 3, wherein removing the solvent from the perovskite precursor droplets after collecting the perovskite precursor droplets on the substrate comprises annealing the perovskite precursor layer, exposing the perovskite precursor layer to sub-atmospheric pressure, submerging or spraying the perovskite precursor layer with an antisolvent, or flowing gas on top of the precursor layer.

Embodiment 5 is the method of embodiment 3 or 4, wherein removing the solvent from the perovskite precursor droplets after collecting the perovskite precursor droplets on the substrate comprises heating the substrate.

Embodiment 6 is the method of any one of embodiments 2-5, wherein the one or more perovskite precursors comprise one or more of methylammonium iodide, methylammonium bromide, methylammonium chloride, formamidinium iodide, formamidinium bromide, formamidinium chloride, cesium iodide, cesium bromide, cesium chloride, lead (II) iodide, lead (II) bromide, lead (II) chloride, rubidium iodide, rubidium bromide, rubidium chloride, tin iodide, tin bromide, tin chloride, germanium iodide, germanium bromide, and germanium chloride.

Embodiment 7 is the method of embodiment 6, wherein the perovskite precursor composition further comprises one or more of phenethylammonium chloride, phenethylammonium iodide, n-octylammonium iodide, n-octylammonium bromide, 1-α-phosphatidylcholine, trimethylphenylammonium tribromide, (benzylamine)trifluoroboron, tetradecyldimethyl(3-sulfopropyl)ammonium hydroxide inner salt, and carbohydrazide.

Embodiment 8 is the method of any one of embodiments 2-7, wherein the solvent is a polar aprotic solvent.

Embodiment 9 is the method of embodiment 8, wherein the solvent comprises one or more of dimethyl sulfoxide, dimethylformamide, γ-butyrolactone, N-methyl-2-pyrrolidone, dimethylacetamide, 2-methoxyethanol, and acetonitrile.

Embodiment 10 is the method of embodiment 2, wherein the perovskite precursor composition is a colloid.

Embodiment 11 is the method of embodiment 10, wherein the one or more perovskite precursors comprise one or more of methylammonium lead iodide, methylammonium tin iodide, methylammonium lead bromide, methylammonium tin bromide, methylammonium lead chloride, methylammonium tin chloride, formamidinium lead iodide, formamidinium tin iodide, formamidinium lead bromide, formamidinium tin bromide, formamidinium lead chloride, formamidinium tin chloride, cesium lead iodide, cesium tin iodide, cesium lead bromide, cesium tin bromide, cesium lead chloride, and cesium tin chloride.

Embodiment 12 is the method of embodiment 11, wherein the solvent is a nonpolar solvent.

Embodiment 13 is the method of embodiment 12, wherein the solvent comprises one or more of hexane, octane, pentane, cyclohexane, benzene, and toluene.

Embodiment 14 is the method of any one of embodiments 1-13, wherein accelerating the perovskite precursor droplets toward the substrate comprises:
transporting the perovskite precursor droplets to a first vacuum chamber with a carrier gas; and
expanding the perovskite precursor droplets through a nozzle into a second vacuum chamber, wherein a pressure in the first vacuum chamber exceeds a pressure in the second vacuum chamber.

Embodiment 15 is the method of embodiment 14, where a pressure in the first and second vacuum chambers is in a range between about 0.001 Torr and about 1 Torr, between about 1 Torr and about 100 Torr, between about 100 Torr and about 300 Torr, or between about 300 Torr and about 760 Torr.

Embodiment 16 is the method of embodiment 15, wherein collecting the perovskite precursor droplets on the substrate comprises translating the substrate with respect to the nozzle.

Embodiment 17 is the method of any one of embodiments 1-16, wherein the perovskite film is a continuous coating on the substrate.

Embodiment 18 is the method of any one of embodiments 1-17, wherein the perovskite film is a conformal coating on the substrate.

Embodiment 19 is the method of any one of embodiments 1-18, wherein the perovskite precursor droplets have a diameter between about 1 μm and about 10 μm, between about 0.002 μm and about 0.15 μm, between about 0.1 μm and about 8 μm, or between about 5 μm and about 80 μm.

Embodiment 20 is the method of any one of embodiments 1-19, wherein the perovskite film comprises perovskite crystal grains having a size between about 0.05 μm and about 0.2 μm, between about 0.2 μm and about 2 μm, or between about 2 μm and about 100 μm.

Embodiment 21 is coated substrate comprising:
a substrate; and
a perovskite precursor composition on the substrate, wherein the perovskite precursor composition comprises a solvent and one or more perovskite precursors, and removing the solvent from the perovskite precursor composition yields a perovskite film on the substrate.

Embodiment 22 is the coated substrate of embodiment 21, wherein the one or more perovskite precursors comprise one or more of methylammonium iodide, methylammonium bromide, methylammonium chloride, formamidinium iodide, formamidinium bromide, formamidinium chloride, cesium iodide, cesium bromide, cesium chloride, lead (II) iodide, lead (II) bromide, lead (II) chloride, rubidium iodide, rubidium bromide, rubidium chloride, tin iodide, tin bromide, tin chloride, germanium iodide, germanium bromide, and germanium chloride.

Embodiment 23 is the coated substrate of embodiment 22, wherein the perovskite precursor composition further comprises one or more of phenethylammonium chloride, phenethylammonium iodide, n-octylammonium iodide, n-octylammonium bromide, 1-α-phosphatidylcholine, trimethylphenylammonium tribromide, (benzylamine)trifluoroboron, tetradecyldimethyl(3-sulfopropyl)ammonium hydroxide inner salt, and carbohydrazide.

Embodiment 24 is the coated substrate of any one of embodiments 21-23, wherein the solvent is a polar aprotic solvent.

Embodiment 25 is the coated substrate of embodiment 24, wherein the solvent comprises one or more of dimethyl sulfoxide, dimethylformamide, γ-butyrolactone, N-methyl-2-pyrrolidone, dimethylacetamide, 2-methoxyethanol, and acetonitrile.

Embodiment 26 is the coated substrate of any one of embodiments 21-25, wherein the one or more perovskite precursors comprise one or more of methylammonium lead iodide, methylammonium tin iodide, methylammonium lead bromide, methylammonium tin bromide, methylammonium lead chloride, methylammonium tin chloride, formamidinium lead iodide, formamidinium tin iodide, formamidinium lead bromide, formamidinium tin bromide, formamidinium lead chloride, formamidinium tin chloride, cesium lead iodide, cesium tin iodide, cesium lead bromide, cesium tin bromide, cesium lead chloride, and cesium tin chloride.

Embodiment 27 is the coated substrate of embodiment 26, wherein the solvent is a nonpolar solvent.

Embodiment 28 is the coated substrate of embodiment 27, wherein the solvent comprises one or more of hexane, octane, pentane, cyclohexane, benzene, and toluene.

Embodiment 29 is a liquid deposition system comprising:
a liquid delivery system;
an atomizer in fluid communication with the liquid delivery system;
a first chamber in fluid communication with the atomizer;
a second chamber;
a vacuum pump in fluid communication with the second chamber;
a nozzle, wherein the first chamber and the second chamber are in fluid communication through the nozzle; and
a substrate translation system configured to translate a substrate relative to the nozzle, such that atomized droplets accelerated through the nozzle from the first chamber to the second chamber form a layer on the substrate.

Embodiment 30 is the liquid deposition system of embodiment 29, further comprising:
an additional liquid delivery system;
an additional atomizer in fluid communication with the additional liquid delivery system;
a third chamber in fluid communication with the additional atomizer; and
an additional nozzle, wherein the third chamber and the second chamber are in fluid communication through the nozzle,
wherein the substrate translation system is configured to translate the substrate relative to the additional nozzle, such that atomized droplets accelerated through the nozzle from the third chamber to the second chamber form a layer on the substrate.

Advantages of the disclosed systems and methods include the following. The feedstock material is perovskite inks (unlike for evaporation techniques), which can be adjusted to yield the desired film composition. The spray coating process distributes droplets uniformly over the substrate surface and without introducing point defects or edge defects (unlike most other solution coating methods, like slot-die coating). The process occurs in rough vacuum, which allows for partial or full evaporation of the solvent in the droplets prior to deposition of the droplets, which in turn enables conformal deposition of textured surfaces (unlike atmospheric pressure spraying techniques). The process can be inline or continuous, and thus compatible with roll-to-roll as well as sheet-to-sheet processing.

The details of one or more embodiments of the subject matter of this disclosure are set forth in the accompanying drawings and the description. Other features, aspects, and advantages of the subject matter will become apparent from the description, the drawings, and the claims.

### BRIEF DESCRIPTION OF DRAWINGS

FIG. 1 is a schematic of a first embodiment of a spray-coating system.

FIG. 2 is a schematic of a second embodiment of a spray-coating system.

FIG. 3 is a schematic of a third embodiment of a spray-coating system.

### DETAILED DESCRIPTION

This disclosure describes processes for spray-coating perovskite inks in a low-vacuum environment. As used herein, “low-vacuum” generally refers to an enclosure with a relatively fewer number of air particles than the standard atmosphere, and the pressure can be as low as 10⁻³ Torr. As used herein, “spray-coating” generally refers to the process of atomizing a perovskite ink, accelerating the perovskite droplets from a high-pressure chamber into a low-pressure chamber (e.g., where both chambers are under low-vacuum), and then depositing them onto a moving substrate. As used herein, a “perovskite ink” generally refers to a liquid solution that can transform into a solid film (e.g., when the solvent is evaporated, and the solutes are left behind) with a perovskite crystal structure of ABX₃, where A is an organic or inorganic cation or a mixture of cations, B is a metal cation or a mixture of cations, and X is a halide anion or a mixture of anions.

To spray-coat the perovskite ink, a liquid delivery system delivers the ink to an atomizer. As used herein, a “liquid delivery system” generally refers to an apparatus that draws perovskite ink from a source and feeds it into an atomizer. As used herein, an “atomizer” generally refers to an apparatus that converts the perovskite ink into micrometer to nanometer-sized droplets.

Once the perovskite ink is atomized, a carrier gas transports the droplets into a high-pressure chamber. As used herein, a “high-pressure chamber” generally refers to an enclosure of any shape under low-vacuum. Once the perovskite droplets enter the high-pressure chamber, they accelerate towards the low-pressure chamber as a result of the pressure difference between the two chambers. As used herein, a “low-pressure chamber” generally refers to an enclosure of any shape under low-vacuum that is connected to the high-pressure chamber but has a lower pressure. This pressure difference is created by connecting the two chambers with a nozzle. As used herein, a “nozzle” generally refers to any shape opening that is small enough to restrict the flow of incoming perovskite droplets and create a pressure difference between the two chambers.

After the perovskite droplets accelerate through the nozzle and into the low-pressure chamber, they impact a moving substrate on its nozzle facing side to create a perovskite film. As used herein, a “perovskite film” generally refers to a solid layer with a perovskite crystal structure of ABX₃, where A is an organic or inorganic cation or a mixture of cations, B is a metal cation or mixture of cations, and X is a halide anion or a mixture of anions. As used herein, a “substrate” generally refers to any solid material that has patterned or flat surfaces. The movement of the substrate is controlled with a substrate translation system. As used herein, a “substrate translation system” generally refers to an apparatus that linearly moves the substrate along one or more directions.

Once the spray-coating of the perovskite ink is complete, the result can be a wet or dry film. As used herein, a “wet film” generally refers to a layer that still contains both the solvent and solutes of the perovskite ink. As used herein, a “dry film” generally refers to a layer that only contains the solutes of the perovskite ink (e.g., the solvent has been evaporated from the perovskite droplets before impacting the substrate). If a wet film is obtained, then one or more post-deposition treatments can be implemented to yield a perovskite film. As used herein, a “post-deposition treatment” generally refers to the process of evaporating or extracting the remaining solvent of the spray-coated film to nucleate and grow the perovskite crystals into a perovskite film. If a dry film is obtained, then a perovskite film has been formed and a post-deposition treatment is optional.

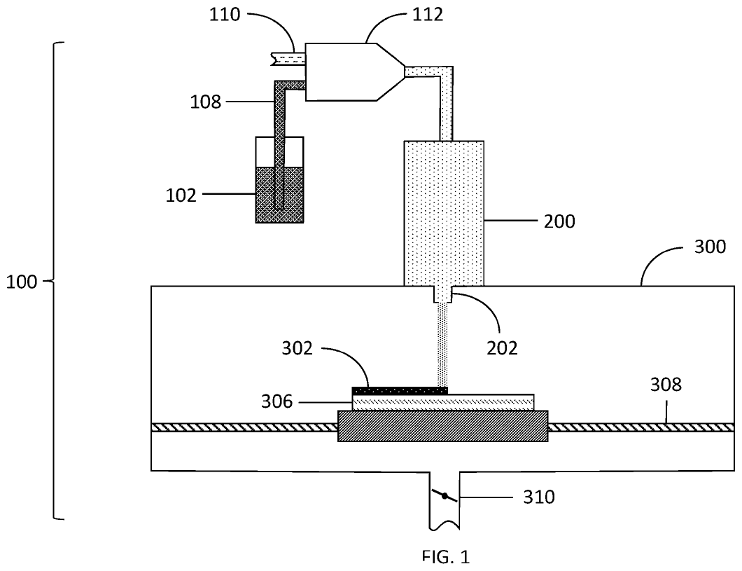

While examples of spray-coating setups and processes are described with respect to FIGS. 1-3, other embodiments can have one or more additional components, or can have one or more components omitted. In some embodiments, the same components can be arranged in a different order. In other embodiments, one or more process conditions can be amended.

FIG. 1 is a schematic of spray-coating setup 100. Spray-coating setup 100 includes perovskite ink 102, liquid delivery system 108, carrier gas 110, atomizer 112, high-pressure chamber 200, nozzle 202, low-pressure chamber 300, perovskite film 302, substrate 306, substrate translation system 308, and vacuum pump valve 310.

Liquid delivery system 108 is configured to deliver perovskite ink 102 to atomizer 112 at a flow rate between about 0.01 ml/min and about 500 ml/min, such as between about 0.1 ml/min and about 10 ml/min to spray-coat a small substrate 306 (e.g., having a width of about 2.5 cm) at a low throughput (e.g., 0.25 m/min), and between about 20 ml/min and about 200 ml/min to spray-coat a large substrate 306 (e.g. having a width of about 15 cm) at a high throughput (e.g. 15 m/min). The optimum value can depend at least in part on the concentration of perovskite ink 102, the width of substrate 306, the desired thickness of perovskite film 302, the desired yield of spray-coating setup 100, the desired throughput of spray-coating setup 100, and the type of apparatus used for atomizer 112. Liquid delivery system 108 should be able to operate continuously without clogging for a minimum of about 1 month.

In some implementations, liquid delivery system 108 includes a syringe pump, which has a flow rate between about 10⁻⁸ ml/min and about 150 ml/min. In other implementations, liquid delivery system 108 includes a peristaltic pump, which has a flow rate between about 0.05 ml/min and about 1000 ml/min. In other implementations, liquid delivery system 108 includes a pressure-driven pump that pressurizes a sealed liquid reservoir with gas to push perovskite ink 102 out through a tube and into atomizer 112. This pump has a flow rate between about 0.1 ml/min and about 100 ml/min, which is controlled by adjusting the pressure difference between the inside of the sealed reservoir and the outlet. In other implementations, liquid delivery system 108 includes a small diaphragm pump, which has a flow rate between about 100 ml/min and about 1000 ml/min. In other implementations, liquid delivery system 108 includes any positive or non-positive pump with a flow rate greater than 0.1 ml/min.

Perovskite ink 102 is configured to be a mixture that transforms into perovskite film 302 after it is spray-coated onto substrate 306, followed by a post-deposition treatment if needed. In some implementations, perovskite ink 102 is a solution with soluble solutes that have a diameter of less than about 1 nm. The solutes are a perovskite precursor including methylammonium iodide, methylammonium bromide, formamidinium iodide, formamidinium bromide, cesium iodide, lead (II) iodide, lead (II) bromide, rubidium iodide, tin iodide, germanium iodide, any combination thereof, or any other suitable perovskite precursor. To improve the quality of perovskite film 302, solute additives such as phenethylammonium chloride, phenethylammonium iodide, n-octylammonium iodide, n-octylammonium bromide, 1-α-phosphatidylcholine, trimethylphenylammonium tribromide, carbohydrazide, any combination thereof, or any other suitable additive can be added to perovskite ink 102. To dissolve the solutes, a polar aprotic solvent is typically used such as dimethyl sulfoxide, dimethylformamide, γ-butyrolactone, N-methyl-2-pyrrolidone, dimethylacetamide, 2-methoxyethanol, acetonitrile, any combination thereof, or any other suitable solvent. The choice of solutes and solvent can depend at least in part on the desired morphology of perovskite film 302 and its optoelectronic properties.

In other implementations, perovskite ink 102 is a colloid with insoluble colloidal particles that have a diameter larger than or equal to about 1 nm. These particles are suspended perovskite crystals in a solvent with a crystal structure of ABX₃, where A is an organic or inorganic cation or a mixture of cations, B is a metal cation or a mixture of cations, and X is a halide anion or a mixture of anions. The colloidal particles are composed of methylammonium lead iodide, methylammonium lead bromide, methylammonium lead chloride, formamidinium lead iodide, formamidinium lead bromide, formamidinium lead chloride, cesium lead iodide, cesium lead bromide, cesium lead chloride, cesium tin iodide, any combination thereof, or any other suitable perovskite compound. To suspend the colloidal particles, a nonpolar solvent is typically used, such as hexane, octane, pentane, cyclohexane, benzene, toluene, any combination thereof, or any other suitable solvent. The optimum choice of colloidal particles and solvent can depend at least in part on the desired morphology of perovskite film 302 and its optoelectronic properties.

Controlling the temperature of perovskite ink 102 can be a parameter that is varied to help achieve the desired morphology of perovskite film 302 and its optoelectronic properties. In some implementations, perovskite ink 102 is temperature-controlled between about −20° C. and about 200° C., such as between about 10° C. and about 28° C. to match the inside wall temperature of high-pressure chamber 200 and low-pressure chamber 300 such that the perovskite droplets do not condense on the chamber walls, and thus avoid large droplets (i.e., millimeter-sized) from depositing onto substrate 306, or between about 30° C. and about 120° C. to increase the solubility of perovskite ink 102 such that for a wet film that undergoes a post-deposition treatment, the perovskite crystal nucleation rate is reduced while the growth rate stays relatively the same to obtain large grains for perovskite film 302, or between about 70° C. and about 180° C. to increase the solvent evaporation rate of the perovskite droplets to obtain a dry perovskite film 302. The optimum temperature for perovskite ink 102 can depend at least in part on the concentration of perovskite ink 102, the chemical composition of perovskite ink 102, the desired degree of how wet or dry the film is after spray-coating, and the desired morphology of perovskite film 302 and its optoelectronic properties. In other implementations, perovskite ink 102 is not temperature-controlled.

Atomizer 112 is configured to break up perovskite ink 102 that is incoming via liquid delivery system 108 into droplets that have a diameter between about 0.001 μm and about 1000 μm, such as between about 0.2 μm and about 1 μm to obtain drier films (i.e., since smaller droplets require less solvent to be evaporated before dry solutes reach substrate 306), and between about 5 μm and about 100 μm to obtain wetter films. Furthermore, when spray-coating on a patterned substrate 306, smaller perovskite droplets typically result in a more conformal perovskite film 302, at least because dry solutes adhere stronger on patterned surfaces than wet solutes. The droplet size can be at least 10 times smaller than the size of the pattern features, such that a conformal film with high surface coverage can be achieved.

Controlling the droplet size distribution produced by atomizer 112 is a parameter that can be varied to help achieve the desired morphology of perovskite film 302 and its optoelectronic properties. In general, the narrower the droplet size distribution is, the more uniform perovskite film 302 will turn out to be morphologically. In some implementations, atomizer 112 is a monodisperse device that produces uniform droplet sizes with a geometric standard deviation less than or equal to about 1.25. In other implementations, atomizer 112 is a polydisperse device that produces non-uniform droplet sizes with a geometric standard deviation greater than about 1.25. The optimum droplet size or distribution of sizes can depend at least in part on the concentration of perovskite ink 102, the chemical composition of perovskite ink 102, if perovskite ink 102 is a colloid or a solution, the desired degree of how wet or dry the film is after spray-coating, the desired degree of how conformal perovskite film 302 is on substrate 306 that has a patterned top surface, the desired morphology of perovskite film 302 and its optoelectronic properties, and the pressure inside high-pressure chamber 200 and low pressure-chamber 300.

In some implementations, atomizer 112 includes a collision nebulizer that produces droplet sizes between about 1 μm and about 10 μm. In other implementations, atomizer 112 includes an electrospray-based aerosol generation technique that produces droplet sizes between about 0.002 μm and about 0.15 μm. In other implementations, atomizer 112 includes a condensation-based aerosol generation technique that produces droplet sizes between about 0.1 μm and about 8 μm. In other implementations, atomizer 112 includes an ultrasonic nozzle that produces droplet sizes between about 5 μm and about 80 μm. In other implementations, atomizer 112 includes any other suitable apparatus that produces either monodisperse or polydisperse droplets that have a diameter between about 0.001 μm and about 1000 μm.

Carrier gas 110 is configured to transport the perovskite droplets (i.e., with low chemical reactivity) from atomizer 112 to high-pressure chamber 200 and control the pressure inside that chamber. The pressure inside high-pressure chamber 200 is a parameter that affects the degree of how wet or dry the film is after spray-coating. Increasing the flow rate of carrier gas 110 will increase the pressure inside high-pressure chamber 200. Consequently, this will reduce the solvent evaporation rate of the perovskite droplets traveling from atomizer 110 to substrate 306. Conversely, reducing the flow rate of carrier gas 110 will reduce the pressure inside high-pressure chamber 200 and increase the solvent evaporation rate of the perovskite droplets. Thus, to obtain a wet film, the pressure inside high-pressure chamber 200 is typically between about 100 Torr and about 400 Torr. To achieve this, carrier gas 110 typically has a flow rate between about 30 SLM and about 400 SLM. On the other hand, to obtain a dry film, the pressure inside high-pressure chamber 200 is typically between about 1 Torr and about 90 Torr. To achieve this, carrier gas 110 typically has a flow rate between about 0.1 SLM and about 25 SLM. The optimum flow rate can depend at least in part on the size of high-pressure chamber 200, the size opening of nozzle 202, the type of apparatus used for atomizer 112, the vacuum pumping capacity, the position of vacuum pump valve 310, and the desired degree of how wet or dry the film is after spray-coating. Carrier gas 110 can be nitrogen, helium, argon, hydrogen, air, any combination thereof, or any other suitable gas.

Controlling the temperature of carrier gas 110 is another parameter that influences the degree of how wet or dry the film is after spray-coating. In some implementations, carrier gas 110 is temperature-controlled between about −100° C. and about 500° C., such as between about 0° C. and about 20° C. to reduce the solvent evaporation rate of the perovskite droplets and obtain a wetter film, or between about 25° C. and about 40° C. to match the inside wall temperature of high-pressure chamber 200 and low-pressure chamber 300 with the temperature of the perovskite droplets such that they do not condense on the chamber walls and thus avoid large droplets (i.e., millimeter-sized) from depositing onto substrate 306, or between about 35° C. and about 150° C. to increase the solvent evaporation rate of the perovskite droplets and obtain a drier film. The optimum temperature for carrier gas 110 can depend at least in part on the desired wall temperature of high-pressure chamber 200 and low-pressure chamber 300, the desired degree of how wet or dry the film is after spray-coating, and the desired morphology of perovskite film 302 and its optoelectronic properties. In other implementations, carrier gas 110 is not temperature-controlled.

In some implementations, if the apparatus used for atomizer 112 requires a gas input to function properly and pressure control of high-pressure chamber 200 is desired, then carrier gas 110 may be introduced into atomizer 112 and high-pressure chamber 200. In this case, in some implementations, the type of gas used for carrier gas 110 and its flow rate are the same for atomizer 112 and high-pressure chamber 200. In other implementations, the type of gas used for carrier gas 110 is the same for atomizer 112 and high-pressure chamber 200, but their flow rates are different. In other implementations, the type of gas used for carrier gas 110 is different for atomizer 112 than high-pressure chamber 200, but their flow rates are the same. In other implementations, the type of gas used for carrier gas 110 and its flow rate are different for atomizer 112 than high-pressure chamber 200.

In other implementations, if the apparatus used for atomizer 112 requires a gas input to function properly and pressure control of high-pressure chamber 200 is not desired, then carrier gas 110 may only be introduced into atomizer 112.

In other implementations, if the apparatus used for atomizer 112 does not require a gas input to function properly and pressure control of high-pressure chamber 200 is desired, then carrier gas 110 may only be introduced into high-pressure chamber 200.

To obtain perovskite film 302, the velocity of the perovskite droplets traveling from atomizer 112 to substrate 306 significantly increases to reach a speed equal to or greater than about Mach 1 to adhere on the surface of substrate 306 upon impaction. This can be achieved by increasing the pressure near atomizer 112 and maintaining or reducing the pressure near substrate 306. This pressure difference will accelerate the perovskite droplets to higher velocities as they approach substrate 306.

In FIG. 1, the pressure difference is created by using high-pressure chamber 200, nozzle 202, low-pressure chamber 300, and vacuum pump valve 310. High-pressure chamber 200 is configured to be an enclosure of any material, shape, and size with an inside pressure that is equal to or higher than 10⁻³ Torr and higher than low-pressure chamber 300. The material of high-pressure chamber 200 can be metal, plastic, glass, or any other suitable material with low chemical reactivity with perovskite ink 102. The shape of high-pressure chamber 200 can be a cuboid, a cylinder, a cube, a cone, any combination thereof, or any other suitable shape with a clear path from its inlet to its outlet.

Nozzle 202 is configured to be a convergent or a convergent-divergent nozzle that connects high-pressure chamber 200 and low-pressure chamber 300. It can have any material, shape opening, and size opening that restricts the flow of the perovskite droplets passing through. The material of nozzle 202 can be metal, plastic, glass, or any other suitable material with low chemical reactivity with perovskite ink 102. The shape opening of nozzle 202 can be a slit or multiple slits, a circle or multiple circles, a square or multiple squares, a ring or multiple rings, any combination thereof, or any other suitable shape opening. The size opening of nozzle 202 is advantageously small enough to create a pressure difference between high-pressure chamber 200 and low-pressure chamber 300 sufficient for the perovskite droplets to reach a minimum velocity of about Mach 1 upon substrate 306 impaction.

Low-pressure chamber 300 is configured to be an enclosure of any material, shape, and size with an inside pressure that is equal to or higher than 10⁻³ Torr, but lower than high-pressure chamber 200. The material of low-pressure chamber 300 can be metal, plastic, glass, or any other suitable material with low chemical reactivity with perovskite ink 102. The shape of low-pressure chamber 300 can be a cuboid, a cylinder, a cube, a cone, any combination thereof, or any other suitable shape with a clear path for substrate translation system 308 to linearly move substrate 306 inside the chamber.

Vacuum pump valve 310 is configured to control the pumping capacity of the vacuum pump that connects to low-pressure chamber 300. Vacuum pump valve 310 can be a butterfly valve, a gate valve, a slit valve, an angle valve, a ball valve, any combination thereof, or any other suitable valve. In some implementations, vacuum pump valve 310 is manually actuated. In other implementations, vacuum pump valve 310 is pneumatically actuated. In other implementations, vacuum pump valve 310 is electrically actuated. In other implementations, vacuum pump valve 310 is actuated using any combination of the aforementioned methods, or any other suitable method or methods.

When vacuum pump valve 310 is fully open, the pressure inside high-pressure chamber 200 and low-pressure chamber 300 will drop to the same value; this value will depend on the pumping capacity of the vacuum pump used. When nozzle 202 is introduced to connect the two chambers, it will create a flow restriction of the incoming perovskite droplets from atomizer 112; consequently, the pressure inside high-pressure chamber 200 will increase, while the pressure inside low-pressure chamber 300 will remain relatively the same. The pressure ratio (i.e., the ratio of the pressure inside high-pressure chamber 200 to the pressure inside low-pressure chamber 300) is an important parameter to control the acceleration of the perovskite droplets from high-pressure chamber 200 to low-pressure chamber 300. The optimum pressure ratio value can depend at least in part on the desired perovskite droplet velocity upon substrate 306 impaction and the desired yield of spray-coating setup 100. In some implementations, the pressure ratio can be reduced by increasing the size opening of nozzle 202, decreasing the flow rate of carrier gas 110, decreasing the vacuum pumping capacity using vacuum pump valve 310, any combination thereof, or any other suitable method. In other implementations, the pressure ratio can be increased by reducing the size opening of nozzle 202, increasing the flow rate of carrier gas 110, increasing the vacuum pumping capacity using vacuum pump valve 310, any combination thereof, or any other suitable method.

In some implementations, nozzle 202, high-pressure 200, and low-pressure chamber 300 are all separate components. In other implementations, nozzle 202 and high-pressure 200 are both one component and low-pressure chamber 300 is a separate component. In other implementations, nozzle 202 and low-pressure chamber 300 are both one component and high-pressure 200 is a separate component. In other implementations, nozzle 202, high-pressure chamber 200, and low-pressure chamber 300 are all one component.

Controlling the wall temperature of high-pressure chamber 200 and low-pressure chamber 300 can be varied to help achieve the desired morphology of perovskite film 302 and its optoelectronic properties. In some implementations, the walls of high-pressure chamber 200 and low-pressure chamber 300 are temperature-controlled between about −200° C. and about 500° C., such as between about 0° C. and about 20° C. to reduce the solvent evaporation rate of the perovskite droplets to obtain a wetter film, or between about 20° C. and about 80° C. to match the perovskite droplet temperature such that they do not condense on the chamber walls and thus avoid large droplets (i.e., millimeter-sized) from depositing onto substrate 306, or between about 30° C. and about 200° C. to increase the solvent evaporation rate of the perovskite droplets to obtain a drier film. The optimum wall temperature for high-pressure chamber 200 and low-pressure chamber 300 depends at least in part on the perovskite droplet temperature, the desired degree of how wet or dry the film is after spray-coating, and the desired morphology of perovskite film 302 and its optoelectronic properties. In other implementations, only the walls of high-pressure chamber 200 are temperature-controlled. In other implementations, only the walls of low-pressure chamber 300 are temperature-controlled. In other implementations, the walls of high-pressure chamber 200 and low-pressure chamber 300 are not temperature-controlled.

Substrate 306 is configured to be the surface onto which perovskite ink 102 is spray-coated on to create perovskite film 302. It can be any solid material that has patterned or flat surfaces and can include one or more materials. Substrate 306 can be glass, silicon, plastic, metals, any combination thereof, or any other suitable material. Substrate 306 can also have one or more layers on top of its nozzle-facing surface. The outermost layer on that surface can be nickel oxide, tin oxide, zinc oxide, copper oxide, copper(I) iodide, silicon oxide, zirconium oxide, titanium oxide, indium tin oxide, indium zinc oxide, hydrogenated indium oxide, indium tungsten oxide, indium cerium oxide, zinc tin oxide, poly[bis(4-phenyl)(2,4,6-trimethylphenyl)amine, poly(N,N′-bis-4-butylphenyl-N,N′-bisphenyl)benzidine, 2,2′,7,7′-tetrakis(N,N-di-p-methoxyphenyl-amine)9,9′-spirobifluorene, poly(3,4-ethylenedioxy thiophene) polystyrene sulfonate, poly(3-hexylthiophene-2,5-diyl), buckminsterfullerene, any combination thereof, or any other suitable layer. The distance between nozzle 202 and substrate 306 can influence a velocity of the perovskite droplets upon substrate 306 impaction. This distance is typically between about 0.5 mm and about 100 mm, such as between about 1 mm and about 5 mm to maximize yield and solute adhesion on substrate 306, or between about 10 mm and about 50 mm to reduce the droplet impaction strength for a softer deposition of perovskite ink 102. The optimum distance can depend at least in part on the desired perovskite droplet velocity upon substrate 306 impaction, the desired yield of spray-coating setup 100, and the desired morphology of perovskite film 302 and its optoelectronic properties.

Substrate translation system 308 is configured to linearly move substrate 306 under nozzle 202 to create perovskite film 302. The translation of substrate 306 can be along one or more axes, and for each axis, the movement can be in one direction or back and forth under nozzle 202. The translation speed is typically between about 0.001 m/min and about 50 m/min, such as between about 10 m/min and about 25 m/min for high throughput applications such as solar cell manufacturing. The optimum translation speed of substrate 306 can depend at least in part on the desired throughput of spray-coating setup 100, the concentration of perovskite ink 102, and the desired thickness of perovskite film 302.

In some implementations, substrate translation system 308, includes a stage and a motion system. The stage can be any solid material that is positioned underneath (e.g., directly underneath) substrate 306 to support its weight and secure it from any movement during the spray-coating process. The motion system includes a stepper motor, a brushed DC motor, a brushless DC motor, a DC servo motor, an AC servo motor, a piezo motor, any combination thereof, or any other suitable apparatus. In some implementations, the motion system can also rotate the stage. In other implementations, the motion system can also tilt the stage. In other implementations, the motion system can also rotate and tilt the stage.

In other implementations, substrate translation system 308 includes rollers to linearly move substrate 306. In this case, the rollers are positioned under substrate 306 and are composed of metal, plastic, glass, or any other suitable material. In some implementations, some of the rollers are electrically powered to translate substrate 306. In other implementations, all of the rollers are electrically powered to translate substrate 306.

In other implementations, substrate translation system 308 includes a roll-to-roll translation process to linearly move substrate 306. In this case, substrate 306 is a roll of plastic, metal, any other flexible and suitable material, or any other flexible and suitable material with one or more layers on its nozzles-facing surface. The rollers can be composed of metal, plastic, glass, or any other suitable material.

In other implementations, substrate translation system 308 includes any other suitable process that can linearly move substrate 306 under nozzle 202 to create perovskite film 302.

Substrate translation system 308 can also be configured to control the temperature of substrate 306. This will enable rapid in situ solvent evaporation control of wet perovskite droplets as soon as they deposit onto substrate 306. Such immediate control over the nucleation and growth rates of the perovskite crystals typically result in obtaining more uniform perovskite film 302 morphologies. In some implementations, substrate 306 is temperature-controlled between about −300° C. and about 500° C., such as between about −300° C. and about −150° C. to freeze the deposited wet film and significantly increase the nucleation rate compared to the growth rate of the perovskite crystals during a post-deposition treatment to obtain small grains for perovskite film 302 (i.e., between about 0.05 μm and about 0.2 μm), and between about 30° C. and about 100° C. to increase both the nucleation and growth rates of the perovskite crystals to obtain medium-sized grains for perovskite film 302 (i.e., between about 0.2 μm and about 2 μm) after a post-deposition treatment if needed, and between about 100° C. and about 200° C. to significantly increase the growth rate compared to the nucleation rate of the perovskite crystals to obtain large grains for perovskite film 302 (i.e., between about 2 μm and about 100 μm) after a post-deposition treatment if needed. The optimum temperature of substrate 306 can depend at least in part on the concentration of perovskite ink 102, the chemical composition of perovskite ink 102, the desired degree of how wet of dry the film is after spray-coating, and the desired morphology of perovskite film 302 and its optoelectronic properties.

In some implementations, the stage, the rollers, or any other component of substrate translation system 308 is temperature-controlled through resistive heating, liquid and/or gas heating and colling, or any combination thereof to control the temperature of substrate 306. In other implementations, the temperature of substrate 306 is controlled with one or more heating lamps. In other implementations, the temperature of substrate 306 is controlled using any other suitable method.

Once the spray-coating of perovskite ink 102 is complete, a post-deposition treatment may be implemented to obtain perovskite film 302. If the spray-coating process yields a dry film, then perovskite film 302 has been formed and no post-deposition treatment is typically required. However, if a morphology or an optoelectronic property change is desired, then a post-deposition treatment can be done. On the other hand, if the spray-coating process yields a wet film, then a post-deposition treatment can be implemented to evaporate or extract the remaining solvent and convert it into perovskite film 302.

In some implementations, the post-deposition treatment is a vacuum quench where the spray-coated film is left inside an enclosure under vacuum to evaporate the remaining solvent. This post-deposition treatment is a good option if medium-sized grains are desired (i.e., between about 0.2 μm and about 2 μm) for perovskite film 302. To quench the spray-coated film, the vacuum pressure is typically between about 700 Torr and about 10⁻⁴ Torr, such as between 200 Torr and about 10 Torr for slow solvent evaporation rates which typically yield larger and less uniform grain sizes for perovskite film 302, or between about 5 Torr and about 10⁻³ Torr for fast solvent evaporation rates which typically yield smaller and more uniform grain sizes for perovskite film 302. The quenching time is typically between about 1 s and about 600 s, such as between 1 s and about 60 s to nucleate the perovskite crystals but not completely evaporate the solvent if a subsequent post-deposition treatment is desired to obtain perovskite film 302, or between about 120 s and about 600 s to nucleate and grow the perovskite crystals by completely evaporating the solvent to obtain perovskite film 302 with no subsequent post-deposition treatment. The optimum vacuum pressure and quench time can depend at least in part on the type of solvent or solvents used for perovskite ink 102, the amount of solvent left after spray-coating, the concentration of perovskite ink 102, the chemical composition of perovskite ink 102, whether or not a subsequent treatment or treatments will follow, the desired grain sizes for perovskite film 302, the desired morphology of perovskite film 302, and the desired optoelectronic properties of perovskite film 302. In some implementations, the vacuum quench is done inside low-pressure chamber 300 and under nozzle 202 without spray-coating perovskite ink 102. In other implementations, the vacuum quench is done inside low-pressure chamber 300 and away from nozzle 202, with or without spray-coating perovskite ink 102. In other implementations, the vacuum quench is done inside any other suitable enclosure under vacuum.

In other implementations, the post-deposition treatment is an anneal of the spray-coated film to evaporate the remaining solvent. This post-deposition treatment is a good option if large grains are desired (e.g., between about 2 μm and about 100 μm) for perovskite film 302. To anneal the spray-coated film, the temperature of substrate 306 is typically between about 30° C. and about 500° C., such as between about 30° C. and about 80° C. for slow solvent evaporation rates which typically yield a continuous perovskite film 302 with large grains, or between about 100° C. and about 150° C. for moderate solvent evaporation rates which typically yield a discontinuous perovskite film 302 with large grains separated from each other, or between about 180° C. and about 250° C. for fast solvent evaporation rates which typically yield a highly discontinuous perovskite film 302 with very large perovskite grains separated from each other. The anneal time is typically between about 0.01 min and about 120 min, such as between about 0.1 min to about 5 min to nucleate and grow the perovskite crystals but not completely evaporate the solvent if a subsequent post-deposition treatment is desired to obtain perovskite film 302, or between about 10 min and about 60 min to nucleate and grow the perovskite crystals by completely evaporating the solvent to obtain perovskite film 302 with no subsequent post-deposition treatment. The optimum anneal temperature and time can depend at least in part on the type of solvent or solvents used for perovskite ink 102, the amount of solvent left after spray-coating, the concentration of perovskite ink 102, the chemical composition of perovskite ink 102, whether or not a subsequent treatment or treatments will follow, the desired grain sizes for perovskite film 302, the desired morphology of perovskite film 302, and the desired optoelectronic properties of perovskite film 302. In some implementations, the anneal is done inside low-pressure chamber 300 and under nozzle 202 without spray-coating perovskite ink 102. In other implementations, the anneal is done inside low-pressure chamber 300 and away from nozzle 202 with or without spray-coating perovskite ink 102. In other implementations, the anneal is done inside another enclosure under vacuum, in ambient atmosphere, or in any other suitable environment. The annealing apparatus can be a hotplate, a furnace, a heating lamp, any combination thereof, or any other suitable apparatus. In some implementations, the annealing apparatus is a sub-component of substrate translation system 308. In other implementations, the annealing apparatus is a separate component from substrate translation system 308.

In other implementations, the post-deposition treatment is a gas quench where the spray-coated film is further dried by blowing gas on top of it to evaporate the remaining solvent. This post-deposition treatment is a good option if medium-sized grains are desired (i.e., between about 0.2 μm and about 2 μm) for perovskite film 302. Since this treatment can typically only partially evaporate the solvent from the spray-coated film, a subsequent post-deposition treatment may be needed. The gas can be air, nitrogen, helium, argon, hydrogen, any combination thereof, or any other suitable gas. To quench the spray-coated film, the distance between the film and the gas outlet needs to between about 0.001 cm and about 30 cm, such as between about 0.01 cm and about 5 cm for fast solvent evaporation rates which typically yield smaller and more uniform grain sizes for perovskite film 302, or between about 10 cm and about 20 cm for slow solvent evaporation rates which typically yield larger and less uniform grain sizes for perovskite film 302. Furthermore, the flow rate of the gas needs to be between about 0.1 SLM and about 300 SLM, such as between about 5 SLM and about 50 SLM for slow solvent evaporation rates which typically yield larger and less uniform grain sizes for perovskite film 302, or between about 100 SLM and about 200 SLM for fast solvent evaporation rates which typically yield smaller and more uniform grain sizes for perovskite film 302. The quenching time is between about 0.5 s and about 600 s, such as between about 1 s to about 240 s to nucleate the perovskite crystals but not completely evaporate the solvent, thus, a subsequent post-deposition treatment is typically required to obtain perovskite film 302, and between about 420 s and about 600 s to nucleate and grow the perovskite crystals but not completely evaporate the solvent, thus, a subsequent post-deposition treatment is typically required to obtain perovskite film 302. In some implementations, the gas is temperature-controlled between about 20° C. and about 300° C., such as between about 30° C. and about 80° C. to increase the solvent evaporation rate which typically yields smaller and more uniform grain sizes for perovskite film 302, or between about 100° C. and 250° C. to increase the solvent evaporation and increase the grow rate of the perovskite crystals which typically yields larger and less uniform grain sizes for perovskite film 302. In other implementations, the gas is not temperature-controlled.

An optimum distance between the spray-coated film and the gas outlet, the gas flow rate, the quench time, and the gas temperature can depend at least in part on the type of solvent or solvents used for perovskite ink 102, the amount of solvent left after spray-coating, the concentration of perovskite ink 102, the chemical composition of perovskite ink 102, which subsequent treatment or treatments will follow, the desired grain sizes for perovskite film 302, the desired morphology of perovskite film 302, and the desired optoelectronic properties of perovskite film 302. In some implementations, the gas quench is done inside low-pressure chamber 300 by using the spray-coating setup 100 disclosed in FIG. 1, and flowing carrier gas 110 instead of spray-coating perovskite ink 102. In other implementations, the gas quench is done inside low-pressure chamber 300 by using the spray-coating setup 100 disclosed in FIG. 1 and adding a second set of high-pressure chamber 200 and nozzle 202 in series with the first original set to flow carrier gas 110 though the second set. In this case, substrate 306 translates under the first nozzle 202 to be spray-coated with perovskite ink 102 and then continues to translate inline under the second nozzle 202 to be quenched with gas. In other implementations, the gas quench is done inside low-pressure chamber 300 by adding any suitable apparatus in series with high-pressure chamber 200 and nozzle 202 to flow gas after spray-coating perovskite ink 102. In other implementations, the gas quench can be done inside another enclosure under vacuum, in ambient atmosphere, or in any other suitable environment using any suitable apparatus that can flow gas. In some implementations, substrate 306 translates in one direction or back and forth under the gas outlet during quenching. In other implementations, substrate 306 is stationary under the gas outlet during quenching.

In other implementations, the post-deposition treatment is an antisolvent bath quench where the spray-coated film is dipped in the bath to extract the remaining solvent. This post-deposition treatment is a good option if medium-sized grains are desired (e.g., between about 0.2 μm and about 2 μm) for perovskite film 302. Since this treatment can only partially extract the solvent from the spray-coated film, a subsequent post-deposition treatment is usually required. The antisolvent bath can be ethanol, isopropanol, butyl alcohol, ethyl acetate, methyl acetate, chloroform, chlorobenzene, butyl acetate, 1,2-dichlorobenzene, anisole, trifluorotoluene, diethyl ether, m-xylene, toluene, mesitylene, any combination thereof, or any other suitable antisolvent bath. To quench the spray-coated film, the antisolvent bath typically has a dipole moment between about 0.1 D and about 3.5 D, such as between about 0.5 D and about 1.2 D for slow solvent extraction rates, which typically yield larger and less uniform gain sizes for perovskite film 302, of between about 1.5 D and about 3 D for fast solvent extraction rates which typically yield smaller and more uniform grain sizes for perovskite film 302.

The quenching time is typically between about 1 s and about 900 s, such as between about 1 s and about 30 s to nucleate the perovskite crystals but not completely extract the solvent, thus, a subsequent post-deposition treatment is typically required to obtain perovskite film 302, of between about 120 s and about 360 s to nucleate and grow the perovskite crystals but not completely evaporate the solvent, thus, a subsequent post-deposition treatment is typically required to obtain perovskite film 302.

In some implementations, the antisolvent bath is temperature-controlled between about −20° C. and about 150° C., such as between about −10° C. and about 10° C. to slow down the solvent extraction rate which typically yields larger and less uniform grain sizes for perovskite film 302, or between about 30° C. and 80° C. to speed up the solvent extraction rate, which typically yields smaller and more uniform grain sizes for perovskite film 302. In other implementations, the antisolvent bath is not temperature-controlled.

The optimum antisolvent bath composition, quenching time, and bath temperature can depend at least in part on the type of solvent or solvents used for perovskite ink 102, the amount of solvent left after spray-coating, the concentration of perovskite ink 102, the chemical composition of perovskite ink 102, which subsequent treatment or treatments will follow, the desired grain sizes for perovskite film 302, the desired morphology of perovskite film 302, and the desired optoelectronic properties of perovskite film 302.

In some implementations, the antisolvent bath quench is done inside low-pressure chamber 300 and under nozzle 202 without spray-coating perovskite ink 102. In other implementations, the antisolvent bath quench is done inside low-pressure chamber 300 and away from nozzle 202 with or without spray-coating perovskite ink 102. In other implementations, the antisolvent bath quench is done inside another enclosure under vacuum, in ambient atmosphere, or in any other suitable environment. In some implementations, substrate 306 translates in and out of the antisolvent bath once or multiple times during the quench. In other implementations, substrate 306 is stationary in the antisolvent bath during the quench.

In other implementations, the post-deposition treatment is an antisolvent spray quench where the spray-coated film undergoes a similar spray-coating process disclosed herein, and perovskite ink 102 is replaced with an antisolvent to extract the remaining solvent. This post-deposition treatment is a good option if medium-sized grains are desired (e.g., between about 0.2 μm and about 2 μm) for perovskite film 302. Since this treatment can only partially extract the solvent from the spray-coated film, a subsequent post-deposition treatment is usually required. The antisolvent can be ethanol, isopropanol, butyl alcohol, ethyl acetate, methyl acetate, chloroform, chlorobenzene, butyl acetate, 1,2-dichlorobenzene, anisole, trifluorotoluene, diethyl ether, m-xylene, toluene, mesitylene, any combination thereof, or any other suitable antisolvent. To quench the spray-coated film, the antisolvent typically has a dipole moment between about 0.1 D and about 3.5 D, such as between about 0.5 D and about 1.2 D for slow solvent extraction rates, which typically yield larger and less uniform gain sizes for perovskite film 302, or between about 1.5 D and about 3 D for fast solvent extraction rates, which typically yield smaller and more uniform grain sizes for perovskite film 302.

In some implementations, the antisolvent liquid is temperature-controlled between about −20° C. and about 150° C., such as between about −10° C. and about 10° C. to slow down the solvent extraction rate which typically yields larger and less uniform grain sizes for perovskite film 302, or between about 30° C. and 80° C. to speed up the solvent extraction rate which typically yields smaller and more uniform grain sizes for perovskite film 302. In other implementations, the antisolvent liquid is not temperature-controlled.

The optimum antisolvent composition and temperature can depend at least in part on the type of solvent or solvents used for perovskite ink 102, the amount of solvent left after spray-coating, the concentration of perovskite ink 102, the chemical composition of perovskite ink 102, which subsequent treatment or treatments will follow, the desired grain sizes for perovskite film 302, the desired morphology of perovskite film 302, and the desired optoelectronic properties of perovskite film 302.

In some implementations, the antisolvent spray quench is done inside low-pressure chamber 300 by using the spray-coating setup 100 disclosed in FIG. 1, and spray-coating antisolvent instead of perovskite ink 102. In other implementations, the antisolvent spray quench is done inside low-pressure chamber 300 by using the spray-coating setup 100 disclosed in FIG. 1, and adding a second set of liquid delivery system 108, carrier gas 110, atomizer 112, high-pressure chamber 200, and nozzle 202 in series with the first original set to spray-coat antisolvent though the second set. In this case, substrate 306 translates under the first nozzle 202 to be spray-coated with perovskite ink 102 and then continues to translate inline under the second nozzle 202 to be spray-coated with antisolvent. In other implementations, the antisolvent spray quench is done inside low-pressure chamber 300 by adding any suitable liquid spray-coating apparatus in series with high-pressure chamber 200 and nozzle 202 to spray-coat the antisolvent after perovskite ink 102. In this case, substrate 306 translates under nozzle 202 to be spray-coated with perovskite ink 102, and then continues to translate inline under the new the spray-coating apparatus to be quenched with antisolvent. In other implementations, the antisolvent spray quench is done inside another enclosure under vacuum, in ambient atmosphere, or in any other suitable environment using any suitable liquid spray-coating apparatus. In some implementations, substrate 306 translates in one direction or back and forth under the antisolvent outlet during quenching. In other implementations, substrate 306 is stationary under the antisolvent outlet during quenching.

In other implementations, the post-deposition treatment is any combination of the aforementioned post-deposition treatments, or any other suitable post-deposition treatment to nucleate and grow the perovskite crystals into perovskite film 302. The optimum post-deposition treatment can depend at least in part on the type of solvent or solvents used for perovskite ink 102, the amount of solvent left after spray-coating, the concentration of perovskite ink 102, the chemical composition of perovskite ink 102, whether or not subsequent treatments will follow, the desired grain sizes for perovskite film 302, the desired morphology of perovskite film 302, and the desired optoelectronic properties of perovskite film 302.

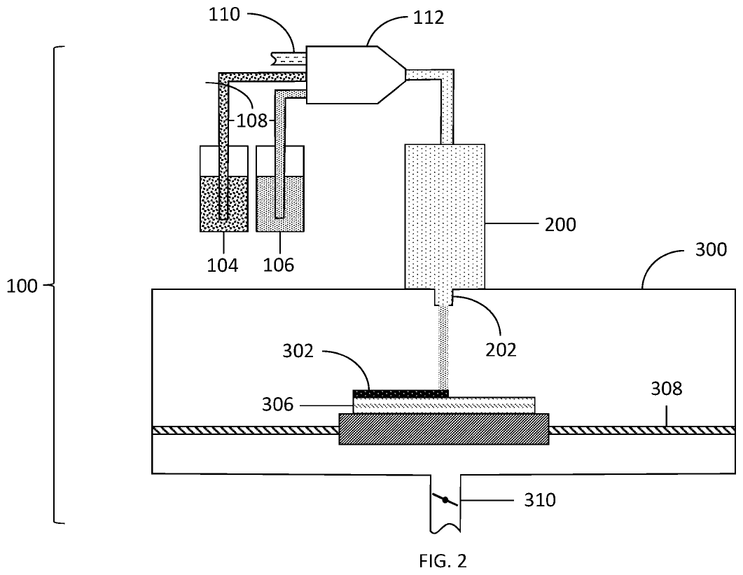

FIG. 2 is a schematic of spray-coating setup 100. Spray-coating setup 100 includes perovskite ink A 104, perovskite ink B 106, two liquid delivery systems 108, carrier gas 110, atomizer 112, high-pressure chamber 200, nozzle 202, low-pressure chamber 300, perovskite film 302, substrate 306, substrate translation system 308, and vacuum pump valve 310. Liquid delivery systems 108, carrier gas 110, atomizer 112, high-pressure chamber 200, nozzle 202, low-pressure chamber 300, perovskite film 302, substrate 306, substrate translation system 308, and vacuum pump valve 310 can be the same as disclosed in FIG. 1 or they can be different.

Perovskite ink A 104 and perovskite ink B 106 from FIG. 2 are configured to be mixtures that transform into perovskite film 302 after they have been simultaneously or sequentially spray-coated onto substrate 306 with a subsequent post-deposition treatment if needed. In a simultaneous spray-coating process, perovskite ink A 104 and perovskite ink B 106 are spray-coated at the same time such that the two inks mix before atomizer 112, inside atomizer 112, or before nozzle 202. In a sequential spray-coating process, however, perovskite ink A 104 is spray-coated first, and after completion, perovskite ink B 106 is spray-coated afterwards.

In some implementations, the solutes of perovskite ink 102 that were disclosed in FIG. 1 can be split into two or more inks; in this case, in some implementations, perovskite ink A 104 and perovskite ink B 106 have the same solutes and solvents. In other implementations, perovskite ink A 104 and perovskite ink B 106 have the same solutes, but different solvents. In other implementations, perovskite ink A 104 and perovskite ink B 106 have the same solvents, but different solutes. In other implementations, perovskite ink A 104 and perovskite ink B 106 have different solutes and different solvents.

The solutes can include perovskite precursors such as methylammonium iodide, methylammonium bromide, formamidinium iodide, formamidinium bromide, cesium iodide, lead (II) iodide, lead (II) bromide, rubidium iodide, tin iodide, germanium iodide, any combination thereof, or any other suitable perovskite precursor. To improve the quality of perovskite film 302, solute additives such as phenethylammonium chloride, phenethylammonium iodide, n-octylammonium iodide, n-octylammonium bromide, 1-α-phosphatidylcholine, trimethylphenylammonium tribromide, carbohydrazide, any combination thereof, or any other suitable additive can be added to perovskite ink A 104 and/or perovskite ink B 106. To dissolve the solutes, a polar aprotic solvent is typically used, such as dimethyl sulfoxide, dimethylformamide, γ-butyrolactone, N-methyl-2-pyrrolidone, dimethylacetamide, 2-methoxyethanol, acetonitrile, any combination thereof, or any other suitable solvent.

In other implementations, perovskite ink A 104 is replaced with perovskite ink 102, and perovskite ink B 106 is replaced with an antisolvent of ethanol, isopropanol, butyl alcohol, ethyl acetate, methyl acetate, chloroform, chlorobenzene, butyl acetate, 1,2-dichlorobenzene, anisole, trifluorotoluene, diethyl ether, m-xylene, toluene, mesitylene, any combination thereof, or any other suitable antisolvent. In other implementations, perovskite ink A 104 is replaced with perovskite ink 102, and perovskite ink B 106 along with its liquid delivery system 108 are removed and replaced with a second carrier gas fluidly coupled to high-pressure chamber 200. In other implementations, either perovskite ink A 104 or perovskite ink B 106 is replaced with perovskite ink 102, and the other ink is replaced by any other suitable liquid or any other suitable gas (e.g., the gas flows directly into high-pressure chamber 200) to obtain perovskite film 302.

In some implementations, the type of apparatus used for liquid delivery system 108 and its flow rate are the same for perovskite ink A 104 and perovskite ink B 106. In other implementations, the type of apparatus used for liquid delivery system 108 is the same for perovskite ink A 104 and perovskite ink B 106, but their flow rates are different. In other implementations, the type of apparatus used for liquid delivery system 108 is different for perovskite ink A 104 than perovskite ink B 106, but their flow rates are the same. In other implementations, the type of apparatus used for liquid delivery system 108 and its flow rate are different for perovskite ink A 104 than perovskite ink B 106.

In some implementations, perovskite ink A 104 and perovskite ink B 106 are both delivered to atomizer 112. In other implementations, perovskite ink A 104 is delivered to a different atomizer than perovskite ink B 106; in this case, the type of apparatus used for atomizer 112, the gas used for carrier gas 110, and the flow rate used for carrier gas 110 can be the same for perovskite ink A 104 and perovskite ink B 106 or they can be different.

In other implementations, any other combinations of the aforementioned arrangements between perovskite ink A 104, perovskite ink B 106, liquid delivery systems 108, atomizer 112, and carrier gas 110 are acceptable, or any other suitable arrangement.

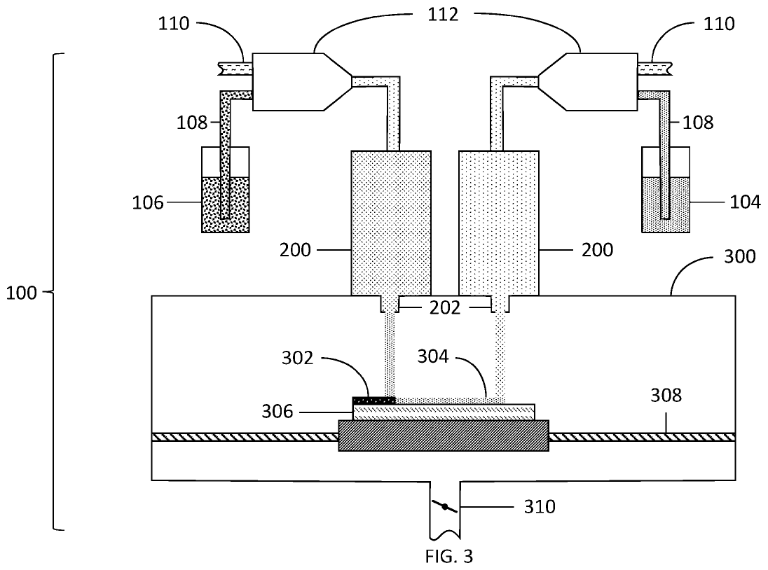

FIG. 3 is a schematic of spray-coating setup 100. Spray-coating setup 100 includes perovskite ink A 104, perovskite ink B 106, two liquid delivery systems 108, two carrier gases 110, two atomizers 112, two high-pressure chambers 200, two nozzles 202, low-pressure chamber 300, precursor layer 304, perovskite film 302, substrate 306, substrate translation system 308, and vacuum pump valve 310. Perovskite ink A 104 and perovskite ink B 106 are the same as disclosed in FIG. 2. Liquid delivery systems 108, carrier gases 110, atomizers 112, low-pressure chamber 300, substrate 306, substrate translation system 308, and vacuum pump valve 310 can be the same as disclosed in FIG. 1 or they can be different.

Perovskite ink A 104 and perovskite ink B 106 from FIG. 3 are configured to be mixtures that transform into perovskite film 302 after they have been sequentially spray-coated onto substrate 306 with a subsequent post-deposition treatment if needed. Unlike the sequential spray-coating process disclosed in FIG. 2 (i.e., where substrate 306 must translate backwards to be spray-coated with perovskite ink B 106 since the two inks share the same nozzle 202), in FIG. 3, after perovskite ink A 104 has been spray-coated, substrate 306 can continue to translate forward under a second nozzle 202 to be spray-coated with perovskite ink B 106. This inline sequential process enables the formation of perovskite film 302 at higher throughputs when using two or more different perovskite inks and a thicker perovskite film 302 without reducing throughput when using two or more of the same ink. In this case, precursor layer 304 is configured to be a dry or wet layer (e.g., after spray-coating perovskite ink A 104) that can transform into perovskite film 302 after one or more layers with the same or different chemical compositions are spray-coated on top of it. In this setup, perovskite ink B 106 typically has its own liquid delivery system 108, carrier gas 110, atomizer 112, high-pressure chamber 200, and nozzle 202.

In some implementations, the solutes of perovskite ink 102 that were disclosed in FIG. 1 can be split into two or more inks. In some implementations, perovskite ink A 104 and perovskite ink B 106 have the same solutes and solvents. In other implementations, perovskite ink A 104 and perovskite ink B 106 have the same solutes, but different solvents. In other implementations, perovskite ink A 104 and perovskite ink B 106 have the same solvents, but different solutes. In other implementations, perovskite ink A 104 and perovskite ink B 106 have different solutes and different solvents.

The solutes typically include a perovskite precursor such as methylammonium iodide, methylammonium bromide, formamidinium iodide, formamidinium bromide, cesium iodide, lead (II) iodide, lead (II) bromide, rubidium iodide, tin iodide, germanium iodide, any combination thereof, or any other suitable perovskite precursor. To improve the quality of perovskite film 302, solute additives such as phenethylammonium chloride, phenethylammonium iodide, n-octylammonium iodide, n-octylammonium bromide, 1-α-phosphatidylcholine, trimethylphenylammonium tribromide, carbohydrazide, any combination thereof, or any other suitable additive can be added to perovskite ink A 104 and/or perovskite ink B 106. To dissolve the solutes, a polar aprotic solvent is typically used, such as dimethyl sulfoxide, dimethylformamide, γ-butyrolactone, N-methyl-2-pyrrolidone, dimethylacetamide, 2-methoxyethanol, acetonitrile, any combination thereof, or any other suitable solvent.

In other implementations, perovskite ink A 104 is replaced with perovskite ink 102, and perovskite ink B 106 is replaced with an antisolvent of ethanol, isopropanol, butyl alcohol, ethyl acetate, methyl acetate, chloroform, chlorobenzene, butyl acetate, 1,2-dichlorobenzene, anisole, trifluorotoluene, diethyl ether, m-xylene, toluene, mesitylene, any combination thereof, or any other suitable antisolvent. In other implementations, perovskite ink A 104 is replaced with perovskite ink 102, and perovskite ink B 106, its liquid delivery system 108 and its atomizer 112 are removed. In this case, carrier gas 110 and high-pressure chamber 200 that would otherwise be associated with perovskite ink B 106 are coupled (e.g., directly connected) to spray gas instead of perovskite ink. In other implementations, either perovskite ink A 104 or perovskite ink B 106 is replaced with perovskite ink 102, and the other ink are replaced by any other suitable liquid, or any other suitable gas (i.e., the gas flows directly into its high-pressure chamber 200) to obtain perovskite film 302.

In some implementations, the type of apparatus used for liquid delivery system 108 and its flow rate are the same for perovskite ink A 104 and perovskite ink B 106. In other implementations, the type of apparatus used for liquid delivery system 108 is the same for perovskite ink A 104 and perovskite ink B 106, but their flow rates are different. In other implementations, the type of apparatus used for liquid delivery system 108 is different for perovskite ink A 104 than perovskite ink B 106, but their flow rates are the same. In other implementations, the type of apparatus used for liquid delivery system 108 and its flow rate are different for perovskite ink A 104 than perovskite ink B 106.

In some implementations, the type of gas and flow rate used for carrier gas 110 are the same for perovskite ink A 104 and perovskite ink B 106. In other implementations, the type of gas used for carrier gas 110 is the same for perovskite ink A 104 and perovskite ink B 106, but their flow rates are different. In other implementations, the type of gas used for carrier gas 110 is different for perovskite ink A 104 than perovskite ink B 106, but their flow rates are the same. In other implementations, the type of gas and flow rate used for carrier gas 110 are different for perovskite ink A 104 than perovskite ink B 106.

In some implementations, the type of apparatus used for atomizer 112 is the same for perovskite ink A 104 and perovskite ink B 106. In other implementations, the type of apparatus used for atomizer 112 is different for perovskite ink A 104 than perovskite ink B 106.

In some implementations, the material, shape, and/or size of high-pressure chamber 200 are the same for perovskite ink A 104 and perovskite ink B 106. In other implementations, the material, shape, and/or size of high-pressure chamber 200 are different for perovskite ink A 104 than perovskite ink B 106.

In some implementations, the material, shape opening, and/or size opening of nozzle 202 are the same for perovskite ink A 104 and perovskite ink B 106. In other implementations, the material, shape opening, and/or size opening of nozzle 202 are different for perovskite ink A 104 than perovskite ink B 106.

In other implementations, any other combinations of arrangements described herein between perovskite ink A 104, perovskite ink B 106, liquid delivery systems 108, atomizers 112, carrier gases 110, high-pressure chambers 200, and nozzles 202 are acceptable, or any other suitable arrangement.

For spray-coating setup 100 disclosed in FIGS. 1-3, in some implementations, one or more components are open to ambient atmosphere. In other implementations, no component is open to ambient atmosphere, and spray-coating setup 100 is entirely under low-vacuum.

For spray-coating setup 100 disclosed in FIGS. 1-3, additional components to improve and/or better control the spray-coating process are acceptable. Additional components include liquid filters, droplet filters, gas heaters, liquid heaters, silicon heaters, mass flow controllers, mass flow meters, liquid flow controllers, liquid flow meters, pressure gauges, diffusion dryers, any combination thereof, or any other suitable component.

The following non-limiting two perovskite film examples were made using spray-coating setups and processes described in this disclosure. In both examples, spray-coating setup 100 disclosed in FIG. 1 was used, liquid delivery system 108 and atomizer 112 were collectively a collision nebulizer, carrier gas 110 was nitrogen, high-pressure chamber 200 was a hollow aluminum cylinder with a diameter of about 2.5 in and a length of about 12 in, nozzle 202 was composed of aluminum with a slit opening that had a length of about 19 mm, a width of about 1.2 mm, and a depth of about 25 mm, low-pressure chamber 300 was a hollow aluminum sphere with an inner diameter of about 7 in, substrate 306 was a polished soda-lime glass with a width and length of about 25 mm and a thickness of about 1.1 mm, the distance between nozzle 202 and substrate 306 was about 3 mm, substrate translation system 308 was comprised of a stage that secured substrate 306, a lead screw, and a linear stepper motor, and vacuum pump valve 310 was a manually-actuated gate valve.

In the first example, perovskite ink 102 was a solution with a concentration of about 1.2 M. It had a stoichiometric solute composition of Cs_{0.05}FA_{0.81}MA_{0.14}Pb_{0.95}(I_{0.86}Br_{0.14})₃ in which the solutes were dissolved in a 1-to-4 dimethyl sulfoxide to dimethylformamide solvent ratio. The amount of ink used was about 3.5 ml. Atomizer 112 was a collision nebulizer that was also a reservoir for perovskite ink 102. Carrier gas 110 had a flow rate of about 33 SLM that went into atomizer 112 to produce droplet sizes between about 1 μm and about 10 μm. Those droplets were transported by carrier gas 110 from atomizer 112 to high-pressure chamber 200 which was held at a pressure of about 200 Torr. The droplets then started to accelerate through nozzle 202 and into low-pressure chamber 300 which was held at a pressure of about 150 Torr. A film started to form on top of substrate 306 as it translated under nozzle 202 at a speed of about 0.45 cm/s. Substrate 306 was composed of polished soda-lime glass with a 30-nm-thick layer of Poly [(9,9-bis(3′-(N,N-dimethylamino)propyl)-2,7-fluorene)-alt-2,7-(9,9-dioctylfluorene)] on top of its nozzle facing side. Once substrate 306 passed nozzle 202 once, carrier gas 110 was shut off, both chambers were vented, and substrate 306 was taken out. The spray-coated film was wet, and thus was immediately quenched in a diethyl ether antisolvent bath for about 15 s to partially extract the solvent and nucleate perovskite crystals. Substrate 306 was subsequently annealed on a hotplate for about 30 min at about 100° C. in ambient atmosphere to evaporate the remaining solvent and grow the perovskite crystals. Once the anneal was complete, an 800-nm-thick perovskite film 302 was formed.

In the second example, perovskite ink 102 was a colloid with a concentration of about 0.09 mg/ml. The colloidal particles were quantum dots with a stoichiometric composition of CsPbI₃. The quantum dots were suspended in hexane and had a diameter between about 5 nm and about 20 nm. The ink was first filtered through a 0.2 μm PTFE filter and the amount used was about 150 ml. Atomizer 112 was a collision nebulizer that was also a reservoir for perovskite ink 102. Carrier gas 110 had a flow rate of about 5 SLM that went into atomizer 112 to produce droplet sizes between about 1 μm and about 10 μm. Those droplets were then transported by carrier gas 110 from atomizer 112 to high-pressure chamber 200 which was held at a pressure of about 50 Torr. The droplets then started to accelerate through nozzle 202 and into low-pressure chamber 300 which was held at a pressure of about 10 Torr. A film started to form on top of substrate 306 as it translated under nozzle 202 at a speed of about 0.22 cm/s. Substrate 306 was composed of polished soda-lime glass with a 100-nm-thick layer of titanium dioxide on top of its nozzle facing side. About two minutes after substrate 306 translated under nozzle 202 back and forth, carrier gas 110 was shut off, both chambers were vented, and substrate 306 was taken out. The spray-coated film was dry, no post-deposition treatment was required, and a 600-nm-thick perovskite film 302 was formed.

Although this disclosure contains many specific details, they should not be interpreted as limitations to the scope of the subject matter or the scope of what is claimed, but rather descriptions of features relevant to particular implementations. Features described in the disclosed embodiments can be combined to derive multiple other embodiments or combinations of other subsets of components. Similarly, features described in the context of implementations that may not be particular to any disclosed embodiment can be combined to derive multiple other embodiments or combinations of other subsets of components.

Particular embodiments of the subject matter have been described. Other embodiments, alterations, and permutations of the described embodiments are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results.

Accordingly, the previously described example embodiments do not define or constrain this disclosure. Other changes, substitutions, and alterations are also possible without departing from the spirit and scope of this disclosure.

1. A method of forming a perovskite film on a substrate, the method comprising:
atomizing a perovskite precursor composition to yield perovskite precursor droplets, wherein the perovskite precursor composition comprises one or more perovskite precursors;
accelerating the perovskite precursor droplets under sub-atmospheric pressure toward the substrate;
collecting the perovskite precursor droplets on the substrate to yield a perovskite precursor layer on the substrate; and
forming, from the perovskite precursor layer on the substrate, a perovskite film on the substrate, wherein the perovskite film has the crystal structure ABX₃, where:
A represents one or more organic cations, one or more inorganic cations, or one or more of both,
B represents one or more metal cations, and
X represents one or more halide anions.

2. The method of claim 1, wherein the perovskite precursor composition further comprises a solvent.

3. The method of claim 2, further comprising removing the solvent from the perovskite precursor droplets before or after collecting the perovskite precursor droplets on the substrate.

4. The method of claim 3, wherein removing the solvent from the perovskite precursor droplets after collecting the perovskite precursor droplets on the substrate comprises annealing the perovskite precursor layer, exposing the perovskite precursor layer to sub-atmospheric pressure, submerging or spraying the perovskite precursor layer with an antisolvent, or flowing gas on top of the precursor layer.

5. The method of claim 3, wherein removing the solvent from the perovskite precursor droplets after collecting the perovskite precursor droplets on the substrate comprises heating the substrate.

6. The method of claim 2, wherein the one or more perovskite precursors comprise one or more of methylammonium iodide, methylammonium bromide, methylammonium chloride, formamidinium iodide, formamidinium bromide, formamidinium chloride, cesium iodide, cesium bromide, cesium chloride, lead (II) iodide, lead (II) bromide, lead (II) chloride, rubidium iodide, rubidium bromide, rubidium chloride, tin iodide, tin bromide, tin chloride, germanium iodide, germanium bromide, and germanium chloride.

7. The method of claim 6, wherein the perovskite precursor composition further comprises one or more of phenethylammonium chloride, phenethylammonium iodide, n-octylammonium iodide, n-octylammonium bromide, 1-α-phosphatidylcholine, trimethylphenylammonium tribromide, (benzylamine)trifluoroboron, tetradecyldimethyl(3-sulfopropyl)ammonium hydroxide inner salt, and carbohydrazide.

8. The method of claim 2, wherein the solvent is a polar aprotic solvent.

9. The method of claim 8, wherein the solvent comprises one or more of dimethyl sulfoxide, dimethylformamide, γ-butyrolactone, N-methyl-2-pyrrolidone, dimethylacetamide, 2-methoxyethanol, and acetonitrile.

10. The method of claim 2, wherein the perovskite precursor composition is a colloid.

11. The method of claim 10, wherein the one or more perovskite precursors comprise one or more of methylammonium lead iodide, methylammonium tin iodide, methylammonium lead bromide, methylammonium tin bromide, methylammonium lead chloride, methylammonium tin chloride, formamidinium lead iodide, formamidinium tin iodide, formamidinium lead bromide, formamidinium tin bromide, formamidinium lead chloride, formamidinium tin chloride, cesium lead iodide, cesium tin iodide, cesium lead bromide, cesium tin bromide, cesium lead chloride, and cesium tin chloride.

12. The method of claim 11, wherein the solvent is a nonpolar solvent.

13. The method of claim 12, wherein the solvent comprises one or more of hexane, octane, pentane, cyclohexane, benzene, and toluene.

14. The method of claim 1, wherein accelerating the perovskite precursor droplets toward the substrate comprises:
transporting the perovskite precursor droplets to a first vacuum chamber with a carrier gas; and
expanding the perovskite precursor droplets through a nozzle into a second vacuum chamber, wherein a pressure in the first vacuum chamber exceeds a pressure in the second vacuum chamber.

15. The method of claim 14, where a pressure in the first and second vacuum chambers is in a range between about 0.001 Torr and about 1 Torr, between about 1 Torr and about 100 Torr, between about 100 Torr and about 300 Torr, or between about 300 Torr and about 760 Torr.

16. The method of claim 15, wherein collecting the perovskite precursor droplets on the substrate comprises translating the substrate with respect to the nozzle.

17. The method of claim 1, wherein the perovskite film is a continuous coating on the substrate.

18. The method of claim 1, wherein the perovskite film is a conformal coating on the substrate.

19. The method of claim 1, wherein the perovskite precursor droplets have a diameter between about 1 μm and about 10 μm, between about 0.002 μm and about 0.15 μm, between about 0.1 μm and about 8 μm, or between about 5 μm and about 80 μm.

20. The method of claim 1, wherein the perovskite film comprises perovskite crystal grains having a size between about 0.05 μm and about 0.2 μm, between about 0.2 μm and about 2 μm, or between about 2 μm and about 100 μm.

21. A coated substrate comprising:
a substrate; and
a perovskite precursor composition on the substrate, wherein the perovskite precursor composition comprises a solvent and one or more perovskite precursors, and removing the solvent from the perovskite precursor composition yields a perovskite film on the substrate.

22-28. (canceled)

29. A liquid deposition system comprising:
a liquid delivery system;
an atomizer in fluid communication with the liquid delivery system;
a first chamber in fluid communication with the atomizer;
a second chamber;
a vacuum pump in fluid communication with the second chamber;
a nozzle, wherein the first chamber and the second chamber are in fluid communication through the nozzle; and
a substrate translation system configured to translate a substrate relative to the nozzle, such that atomized droplets accelerated through the nozzle from the first chamber to the second chamber form a layer on the substrate.

30. (canceled)
